(19) United States
(12) Patent Application Publication
(10) Pub. No.: US 2012/0084029 A1
(43) Pub. Date: Apr. 5, 2012

(54) ELECTRONIC WATT-HOUR METER MANAGING MULTIPLE INPUT SIGNALS AND METHOD OF CALCULATING WATT-HOURS

(75) Inventor: Shin Jae KANG, Gunpo (KR)

(73) Assignees: KOREA ELECTRIC POWER CORPORATION.; SAMSUNG ELECTRO-MECHANICS CO., LTD.

(21) Appl. No.: 13/246,523

(22) Filed: Sep. 27, 2011

(30) Foreign Application Priority Data
Sep. 30, 2010 (KR) 10-2010-0095466

(51) Int. Cl. G01R 21/06; G06F 19/00; G01R 19/255

(52) U.S. Cl. 702/61; 324/120

(57) ABSTRACT

There are provided an electronic watt-hour meter capable of processing a plurality of input signals and a method of calculating watt-hours. The electronic watt-hour meter includes: a signal sensor sensing analogue type voltage and current signals; a multiplexer selectively outputting any one signal of the sensed voltage and current signals; a signal converter converting the selectively outputted signal into a digital signal; a demultiplexer outputting the converted digital signal through a port corresponding to the converted digital signal; and a calculator calculating watt-hours based on the converted digital signal, thereby allowing for a reduction in power consumption and the miniaturizing of the watt-hour meter.

### CROSS-REFERENCE TO RELATED APPLICATIONS

This application claims the priority of Korean Patent Application No. 10-2010-0095466 filed on Sep. 30, 2010, in the Korean Intellectual Property Office, the disclosure of which is incorporated herein by reference.

### BACKGROUND OF THE INVENTION

1. Field of the Invention

The present invention relates to watt-hour calculation, and more particularly, to an electronic watt-hour meter capable of being miniaturized by replacing a plurality of signal converters with one signal converter using a multiplexer and disposing a separate phase delay unit in consideration of phase delay due to the multiplexer, and a method of calculating watt-hours.

2. Description of the Related Art

Recently, interest in the so-called “smart grid” has been progressively increasing. The concept of a smart grid refers to an intelligent electric power grid system which integrates information and communications technology into the production, transportation, and consumption processes of electricity, such that a power provider and a power consumer are able to interact, thereby allowing for the improvement of efficiency. The power provider may prepare for an electric power shortage by identifying expected power use by users in real time through IT media. On the other hand, the users may determine their power usage patterns by identifying their power consumption and associated costs in real time from the power provider.

In the case of the smart grid, it is necessary to smoothly exchange information through an information communication network between the power provider and the users. In addition, an electronic watt-hour metering technology accurately metering consumed watt-hours and converting the consumed watt-hours into digital information and a communication technology transmitting the converted digital information are required.

Meanwhile, an inductive watt-hour meter has been mainly used as the watt-hour meter according to the related art. The inductive watt-hour meter displays consumed watt-hours through a rotative analogue gauge board. The analogue type watt-hour meter has a difficulty in converting consumed watt-hour into the digital information, thereby having a difficulty in the transmission of information through the information communication network. Accordingly, a recently supplied electronic watt-hour meter may convert the consumed watt-hour into digital information through a semiconductor circuit device, such as an analog to digital converter, provided therein and transmit the converted information to the outside through a communication module.

However, in the case of the electronic watt-hour meter, circuits for performing signal conversion with respect to sensed voltage and current signals should be added. Therefore, in the case of a single-phase electronic watt-hour meter, at least two signal conversion circuits should be added, and in the case of a three-phase electronic watt-hour meter, at least six signal conversion circuits should be added. As a result, there are limitations, in that miniaturizing the watt-hour meter is difficult and the power consumption thereof is large.

### SUMMARY OF THE INVENTION

An aspect of the present invention provides an electronic watt-hour meter capable of being miniaturized and reducing power consumption through the reduction of additional circuits, and a method of calculating watt-hours.

Another aspect of the present invention provides an electronic watt-hour meter capable of removing a phase difference between sensed current and voltage and accurately calculating watt-hours, and a method of calculating watt-hours. According to an aspect of the present invention, there is provided an electronic watt-hour meter, including: a signal sensor sensing analogue type voltage and current signals; a multiplexer selectively outputting any one signal of the sensed voltage and current signals; a signal converter converting the selectively outputted signal into a digital signal; a demultiplexer outputting the converted digital signal through a port corresponding to the converted digital signal; and a calculator calculating watt-hours based on the converted digital signal.

The electronic watt-hour meter may further include a phase delay unit delaying any one signal of the sensed voltage and current signals by a predetermined delay angle based on the other signal.

The delay angle may be a value caused by the multiplexer.

According to another aspect of the present invention, there is provided a method of calculating watt-hours, including: (a) sensing analogue type voltage and current signals in a signal sensor; (b) selectively outputting any one signal of the sensed voltage and current signals in a multiplexer; (c) converting the selectively outputted signal into a digital signal in a signal converter; (d) outputting the converted digital signal through a port corresponding to the converted digital signal in a demultiplexer; and (e) calculating watt-hours based on the converted digital signal in a calculator.

The step (a) may further include delaying any one signal of the sensed analog type voltage and current signals by a predetermined delay angle based on the other signal.

The delay angle may be a value caused by the multiplexer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a view showing a configuration of an electronic watt-hour meter in consideration of phase delay according to a first exemplary embodiment of the present invention;

FIG. 2 is a view showing a configuration of an electronic watt-hour meter in consideration of phase delay according to a second exemplary embodiment of the present invention;

FIG. 3 is a view describing phase delay caused by a multiplexer shown in FIG. 1;

FIG. 4 is a view showing a function of a phase delay unit for solving the phase delay shown in FIG. 3;

FIG. 5 is a view showing a configuration of an electronic watt-hour meter for sensing three-phase power according to an exemplary embodiment of the present invention; and

FIG. 6 is a flow chart describing a method of calculating watt-hours according to an exemplary embodiment of the present invention.

### DETAILED DESCRIPTION OF THE PREFERRED EMBODIMENT

Hereinafter, exemplary embodiments of the present invention will be described in detail with reference to the accompanying drawings. The exemplary embodiments of the present invention may be modified in many different forms and the scope of the invention should not be construed as being limited to the embodiments set forth herein. Rather, these embodiments are provided so that this disclosure will be thorough and complete, and will fully convey the concept of the invention to those skilled in the art. Further, throughout the drawings, the same or similar reference numerals will be used to designate the same components or like components having the same functions in the scope of the similar idea.

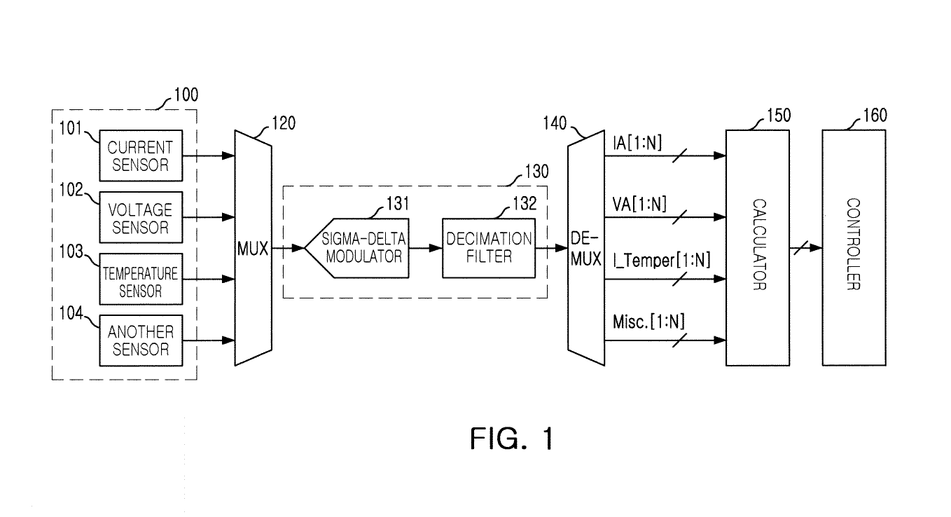

FIG. 1 is a view showing a configuration of an electronic watt-hour meter in consideration of phase delay according to a first exemplary embodiment of the present invention. The electronic watt-hour meter may include a signal sensor 100, a multiplexer 120, a signal converter 130, a demultiplexer 140, a calculator 150, and a controller 160.

The signal sensor 100 senses voltage, current, temperature, or the like, on a single-phase power line or a three-phase power line, which may be an analog type of signal, and transfers the sensed signal to the multiplexer 120. Specifically, the signal sensor 100 may include a current sensor 101, a voltage sensor 102, a temperature sensor 103, and another sensor 104 sensing other signals.

The current sensor 101 senses current flowing on the single-phase or three-phase power line, and transfers the sensed current to the multiplexer 120. The current sensor 101 may use a current transformer in order to sense the current.

The voltage sensor 102 senses voltage on the single-phase or three-phase power line, and transfers the sensed voltage to the multiplexer 120. The voltage sensor 102 may use two divided resistors in order to sense the voltage.

Meanwhile, the turns ratio of the current transformer and divided resistor values are set such that values sensed in the current sensor 101 and the voltage sensor 102 are reduced to several thousandths of the real values on a corresponding power line.

The temperature sensor 103 senses a temperature and transfers the sensed temperature to the multiplexer 120.

Another sensor 104 may be used for sensing required signals other than the above-mentioned current, voltage and temperature, for example, a signal for preventing the theft of the watt-hour meter.

The multiplexer 120 selects one of several input lines to connect the selected input line to a single output line. Any one of the voltage and the current transferred from the signal sensor 100 is selectively transferred to the signal converter 130 by the multiplexer 120.

The signal converter 130 converts an analog type of voltage or current transferred from the multiplexer 120 into a digital signal. Specifically, according to an exemplary embodiment of the present invention, the signal converter 130 may include a sigma-delta modulator 131 and a decimation filter 132. By using these, it is possible for the sigma-delta modulator 131 to obtain characteristics such as high accuracy, high sensitivity, and the like.

The sigma-delta modulator 131 of the signal converter 130 sample the value transferred from the multiplexer 120 into an over-sampling frequency. The sampled over-sampling signal is transferred to the decimation filter 132.

The decimation filter 132 of the signal converter 130 generates the digital signal in which the over-sampled signal transferred from the sigma-delta modulator 131 is restored to an original sampling frequency. The generated digital signal is transferred to the demultiplexer 140.

The demultiplexer 140 performs an opposite function to the multiplexer 120, and outputs a signal inputted through an input line via any one of a plurality of output lines . The digital signal transferred from the signal converter 130, that is, any one of the voltage and the current is selectively transferred to the calculator 150 through a corresponding output port by the demultiplexer 140.

The calculator 150 calculates watt-hours such as effective power or reactive power, power factor, and the like, based on the voltage or the current, which is the digital signal, transferred from the demultiplexer 140. The watt-hours calculation is transferred to the controller 160.

The controller 160 may display the watt-hours, the power factor, and the like, transferred from the calculator 150, store them in a memory, or transmit them to an external apparatus.

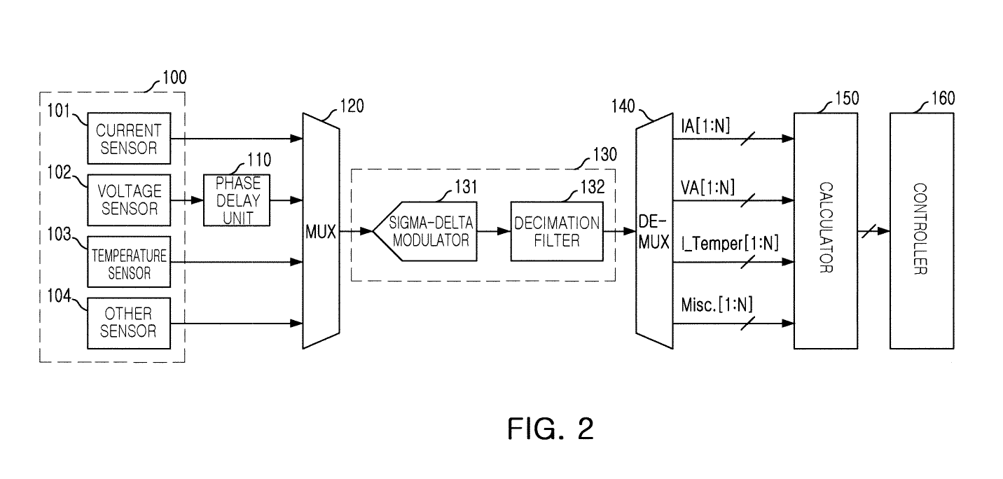

FIG. 2 is a view showing a configuration of an electronic watt-hour meter in consideration of phase delay according to a second exemplary embodiment of the present invention. The electronic watt-hour meter may be configured to further include a phase delay unit 110 unlike FIG. 1. A description of aspects overlapping with the content described with reference FIG. 1 will be omitted for the simplification of the description of the present invention. Only the phase delay unit 110 will be described below.

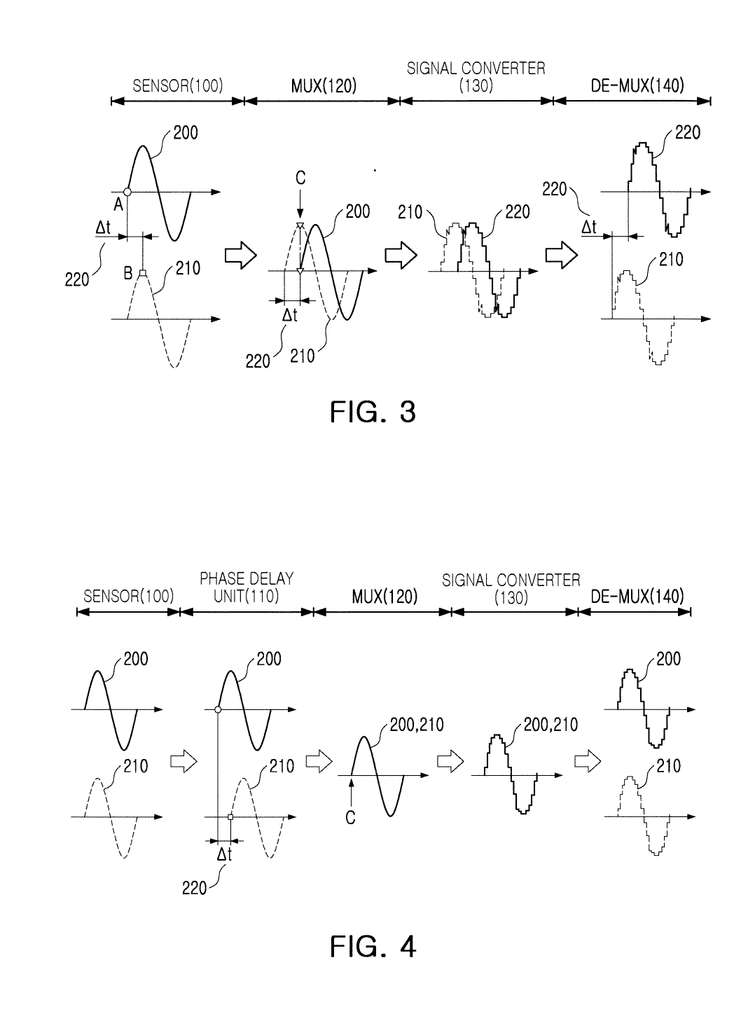

In the case of the electronic watt-hour meter having the configuration as shown in FIG. 1, phase delay due to the multiplexer 120 may occur. Accordingly, the phase delay unit 110 delays any one signal of the sensed voltage and the sensed current transferred to the signal sensor 100 by a predetermined delay angle and transfers the delayed signal to the multiplexer. As such, when a predetermined phase delay is provided, the phase delay due to the multiplexer 120 may be compensated. The delay angle, which is a value caused by the multiplexer 120, will be described in detail with reference to FIGS. 3 and 4.

FIG. 3 is a view describing phase delay caused by the multiplexer shown in FIG. 1, and FIG. 4 is a view showing a function of a phase delay unit for solving the phase delay shown in FIG. 3.

Referring to FIG. 3, the signal sensor 100 senses analog type current 200, and voltage 210 signals, in real time to transfer the sensed current and voltage signals to a multiplexer 120, and the multiplexer 120 selects only one of a plurality of input signals, such as the current 200 or the voltage 210 to transfer one streamlined signal having a predetermined time interval to the signal converter 130. When the current 200 and the voltage 210 sensed in the sensor 100 have the same phase as that shown in FIG. 3, the multiplexer 120 selects the value of the current 200 at a point in time (A) , and then selects the value of the voltage 210 at a point in time (B) after a predetermined time elapse. As a result, the current 200 and the voltage 210 may have a predetermined time interval 220 (Δt) based on the same point in time (C), and a phase difference between the current 200 and the voltage 210 may occur due to the time interval 220 (Δt). The phase difference may also occur in the signal converter 130 and a demultiplexer 140. As a result, a calculator 150 may generate a sensing error. In order to solve this defect, the phase delay unit 110 is disposed between the signal sensor 100 and the multiplexer 120 in a second exemplary embodiment shown in FIG. 2.

An effect due to the phase delay unit 110 will be described with reference to FIG. 4.

Referring to FIG. 4, when the current 200 and the voltage 210 sensed in the sensor 100 have the same phase as shown in FIG. 4, the phase delay unit 110 delays any one of the current 200 and the voltage 210 by the predetermined delay angle and outputs the delayed one. According to an exemplary embodiment of the present invention, the voltage 210 is delayed by the predetermined time interval 220 (Δt). Then, the multiplexer 120 selectively outputs the current 200 and the delay voltage 210 at a predetermined period, thereby transferring one streamlined signal to the signal converter 130. Since the phase delay caused by the multiplexer 120 is previously compensated by the phase delay unit 110 disposed at an input end of the multiplexer 120, the current 200 and the voltage 210 may have the same phase at the predetermined point in time (C), as shown in FIG. 4. Meanwhile, since the temperature sensed in the temperature sensor 103 needs not to consider phases as in the current 200 and the voltage 210, the phase delay unit 110 does not need to be provided.

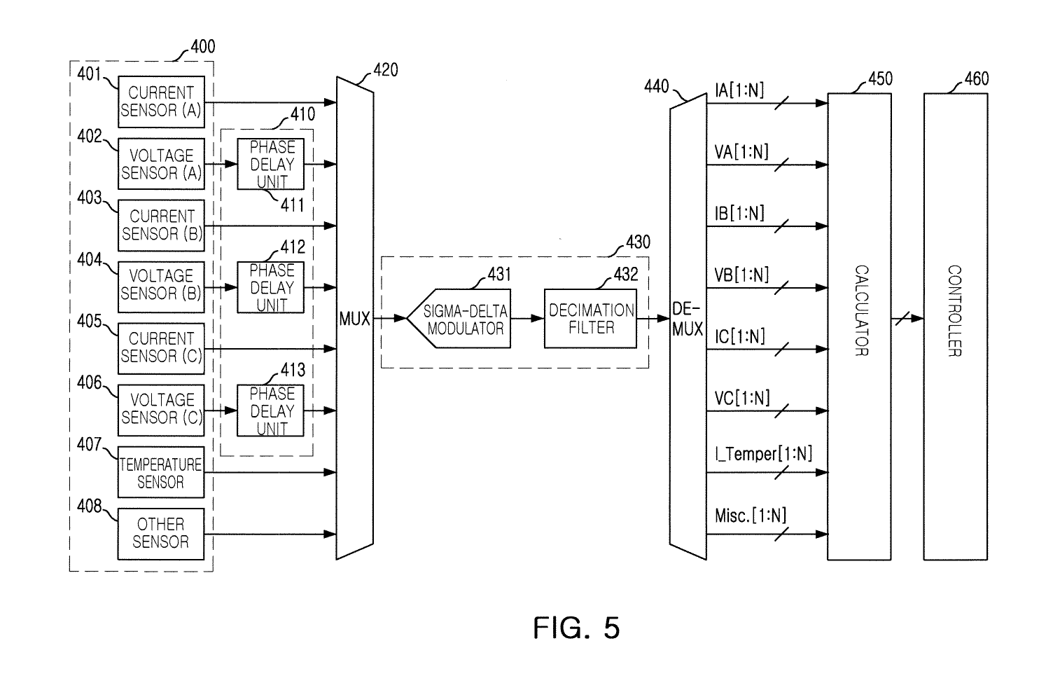

FIG. 5 is a view showing a configuration of an electronic watt-hour meter for calculating three-phase power according to an exemplary embodiment of the present invention. While FIGS. 1 and 2 show the electronic watt-hour meter for calculating single-phase power, FIG. 5 shows the electronic watt-hour meter for calculating three-phase power.

Accordingly, operations of other sensors 407 and 408, a multiplexer 420, signal converters 430, 431, and 432, a demultiplexer 440, a calculator 450, and a controller 460 are the same as those in FIGS. 1 to 4, except that a signal sensor 400 has three pairs (A, B, and C) of current and voltage sensors (401 to 406). Therefore, a detailed description thereof will be omitted.

The signal sensor 400 includes sensors 401 and 402 sensing current and voltage on an A phase of a power line, sensors 403 and 404 sensing current and voltage on a B phase thereof, and sensors 405 and 406 sensing current and voltage on a C phase thereof.

In addition, FIG. 5 shows that phase delay units 410, 412, and 413 are disposed between the output ends of the voltage sensors 402, 404, and 406 on the individual phases A, B, and C, and the signal converter 430. However, the present invention is not limited thereto but the phase delay units 410, 412, and 413 may also be disposed between the output ends of the current sensors 401, 403, and 405 and the signal converter 430. According to another exemplary embodiment, the phase delay units 410, 412, and 413 may be omitted as described with reference to FIG. 1.

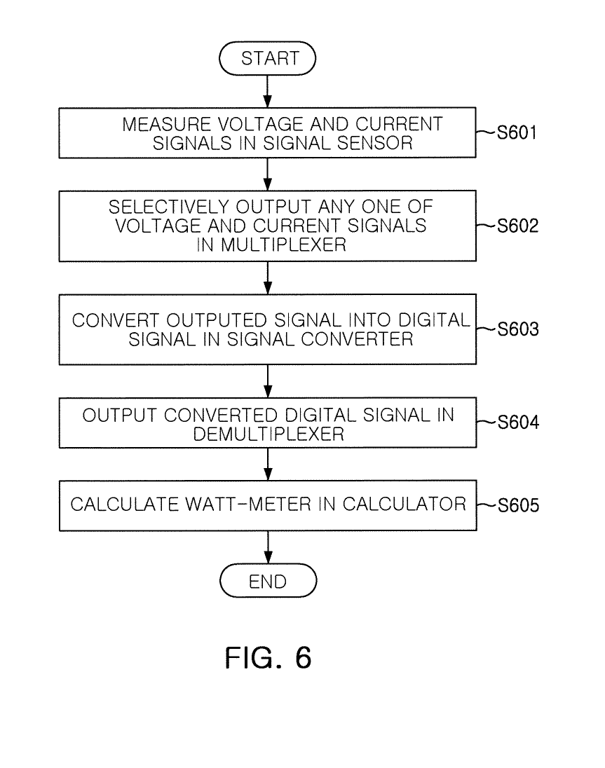

FIG. 6 is a flow chart describing a method of calculating watt-hours according to an exemplary embodiment of the present invention. A description of aspects overlapping with the content described with reference FIGS. 1 to 5 will be omitted for the simplification of the description of the present invention.

Referring to FIG. 6, in an operation (S601), the signal sensor 100 senses the voltage or current on the single-phase or three-phase power line, which may be an analog type of signal and transfers the sensed voltage or current to the multiplexer 120. According to another embodiment of the present invention, the phase delay unit 110 may be disposed between the signal sensor 100 and the multiplexer 120 in order to compensate for the phase delay due to the multiplexer 120.

In an operation (S602), the multiplexer 120 selectively transfers any one of the voltage and the current transferred from the signal sensor 100 to the signal converter 130.

In an operation (S603), the signal converter 130 converts the voltage or current transferred from the multiplexer 120 into a digital signal. Specifically, according to an exemplary embodiment of the present invention, the signal converter 130 may include the sigma-delta modulator 131 and the decimation filter 132. By using the sigma-delta modulator 131, characteristics such as high accuracy, high sensitivity, and the like may be obtained.

Then, in an operation (S604), a multiplexer 140 selectively transfers any one of the voltage and the current, which is the digital signal transferred from the signal converter 130, to the calculator 150 through the corresponding output port.

In an operation (S605), the calculator 150 calculates watt-hours such as effective power or reactive power, power factor, and the like, based on the digital signal, that is, the voltage or the current, transferred from the demultiplexer 140.

The calculated watt-hours, the power factor, or the like, is transferred to the controller 160. Then, the controller 160 may display the watt-hours, the power factor, and the like, transferred from the calculator 150, store them in a memory, or transmit them to an external apparatus.

The present invention may also be implemented as a computer-readable code in a computer-readable recording medium. The computer-readable recording media includes all types of recording apparatuses in which data readable by a computer system is stored. Examples of the computer-readable recording media may include a ROM, a RAM, a CD-ROM, a magnetic tape, a floppy disk, an optical data storage device, etc. Further, the computer-readable recording media are distributed on computer systems connected through the network, such that the computer-readable code may be stored and executed in a distributed scheme.

As set forth above, according to the exemplary embodiments of the present invention, a plurality of signal converters are replaced with one signal converter, thereby allowing for a reduction in power consumption through a reduction of additional circuits and the miniaturizing of the watt-hour meter.

In addition, according to the exemplary embodiments of the present invention, a phase of any one of the sensed current and voltage is delayed by a predetermined angle in order to solve phase delay due to the added multiplexer, thereby allowing for removing a phase difference between the sensed current and voltage and accurately calculating watt-hours.

The exemplary embodiments of the present invention have been described with reference to the accompanying drawings.

Herein, specific terms have been used, but are just used for the purpose of describing the present invention and are not used for qualifying the meaning or limiting the scope of the present invention, which is disclosed in the appended claims. Therefore, it will be appreciated to those skilled in the art that various modifications are made and other equivalent embodiments are available. Accordingly, the actual technical protection scope of the present invention must be determined by the spirit of the appended claims.

What is claimed is:

1. An electronic watt-hour meter, comprising:
a signal sensor sensing analogue type voltage and current signals;
a multiplexer selectively outputting any one signal of the sensed voltage and current signals;
a signal converter converting the selectively outputted signal into a digital signal;
a demultiplexer outputting the converted digital signal through a port corresponding to the converted digital signal; and
a calculator calculating watt-hours based on the converted digital signal.

2. The electronic watt-hour meter of claim 1, further comprising a phase delay unit delaying any one signal of the sensed voltage and current signals by a predetermined delay angle based on the other signal.

3. The electronic watt-hour meter of claim 2, wherein the delay angle is a value caused by the multiplexer.

4. A method of calculating watt-hours, comprising:
(a) sensing analogue type voltage and current signals in a signal sensor;
(b) selectively outputting any one signal of the sensed voltage and current signals in a multiplexer;
(c) converting the selectively outputted signal into a digital signal in a signal converter;
(d) output the converted digital signal through a port corresponding to the converted digital signal in a demultiplexer; and
(e) calculating watt-hours based on the converted digital signal in a calculator.

5. The method of calculating watt-hours of claim 4, wherein step (a) further includes delaying any one signal of the sensed analog type voltage and current signals by a predetermined delay angle based on the other signal.

6. The method of calculating watt-hours of claim 5, wherein the delay angle is a value caused by the multiplexer.
